(19) United States
(12) Patent Application Publication
(10) Pub. No.: US 2023/0251863 A1
(43) Pub. Date: Aug. 10, 2023

(54) MULTI-BIT REGISTER, CHIP, AND COMPUTING APPARATUS

(71) Applicant: SHENZHEN MICROBT ELECTRONICS TECHNOLOGY CO., LTD., GUANGDONG (CN)

(72) Inventors: Wenbo TIAN, GUANGDONG (CN); Zhijun FAN, GUANGDONG (CN); Zuoxing YANG, GUANGDONG (CN); Nan LI, GUANGDONG (CN); Weixin KONG, GUANGDONG (CN)

(21) Appl. No.: 18/005,281

(22) PCT Filed: Jul. 7, 2021
(86) PCT No.: PCT/CN2021/104859

§ 371 Date: Jan. 12, 2023

(30) Foreign Application Priority Data
Nov. 23, 2020 (CN) 202011320660.X

(51) Int. Cl. G06F 9/30

(52) U.S. Cl. CPC G06F 9/30112

(57) ABSTRACT

A multi-bit register (200), a chip, and a computing apparatus, the multi-bit register (100) including: a plurality of register units (210-1, 210-2, . . . , 210-N), each of which is configured to store a bit of data, and the plurality of register units (210-1, 210-2, . . . , 210-N) being connected in parallel to each other; a clock buffer configured to provide a clock signal for the plurality of register units (210-1, 210-2, . . . , 210-N), wherein the plurality of register units (210-1, 210-2, . . . , 210-N) is arranged into an array of register units, and the clock buffer is arranged at an intervening position of the array of register units (210-1, 210-2, . . . , 210-N).

### CROSS-REFERENCE TO RELATED APPLICATIONS

This application is based on and claims priority to Chinese Patent Application No. 202011320660.X filed on Nov. 23, 2020, the disclosure of which is incorporated herein by reference in its entirety.

### TECHNICAL FIELD

The present disclosure relates to semiconductor technologies. Specifically, the present disclosure relates to a multi-bit register, a chip including the multi-bit register, and a computing apparatus.

### BACKGROUND

In semiconductor technologies, registers are very wide in application, and can be used for registering, shifting, and frequency division of digital signals, etc. A register has a data input end, a clock input end, and a data output end. Data can be written into the register through the data input end and read from the register through the data output end. The clock input end is used to receive a clock signal for triggering the register. Commonly used registers include a D flip-flop and a latch, wherein the D flip-flop is clock-edge-triggered while the latch is level-triggered.

In some applications, a group of registers needs to be used to store multi-bit data. That is, a plurality of registers needs to work synchronously. Therefore, data input ends and data output ends of the plurality of registers may be connected in parallel to form a group of registers, and a clock buffer is used to provide a clock signal for the group of registers, thereby forming a multi-bit register.

FIG. 1 is a schematic diagram of a multi-bit register 100 according to the related art. The multi-bit register 100 is configured to store multi-bit data.

As shown in FIG. 1, the multi-bit register 100 includes a group of registers 110 and a clock buffer 120.

The group of registers 110 includes N register units 110-1, 110-2, . . . , and 110-N connected in parallel, and is configured to store the multi-bit data having N bits. Each of the register units 110-1, 110-2, . . . , and 110-N is configured to store a bit of the data. For example, the register unit 110-1 is configured to store a first bit of the multi-bit data, the register unit 110-2 is configured to store a second bit of the multi-bit data, and the like. Data input ends and data output ends of the N register units 110-1, 110-2, . . . , and 110-N are respectively connected in parallel, thereby synchronously storing the bits of the multi-bit data.

The clock buffer 120 is configured to provide a clock signal for the N register units 110-1, 110-2, . . . , and 110-N of the group of registers 110. The clock buffer 120 receives a clock signal from a clock signal end CK and buffers the clock signal, after which the clock signal is input to clock input ends of the N register units 110-1, 110-2, . . . , and 110-N, respectively, thereby triggering the register units 110-1, 110-2, . . . , and 110-N to latch or read out the data.

As shown in FIG. 1, in the related art, the N register units 110-1, 110-2, . . . , and 110-N are generally arranged into one column, and the clock buffer 120 is generally arranged on the periphery of an array formed by the N register units 110-1, 110-2, . . . , and 110-N. That is, as shown in FIG. 1, the clock buffer 120 is arranged at the top or bottom of the N register units 110-1, 110-2, . . . , and 110-N forming the one column.

### SUMMARY

According to an aspect of the present disclosure, a multi-bit register is provided, which includes: a plurality of register units, each of which is configured to store a bit of data, and the plurality of register units being connected in parallel to each other; and a clock buffer configured to provide a clock signal for the plurality of register units, wherein the plurality of register units is arranged into an array of register units, and the clock buffer is arranged at an intervening position of the array of register units.

According to another aspect of the present disclosure, a chip is provided, which includes the multi-bit register described above.

According to still another aspect of the present disclosure, a computing apparatus is provided, which includes the chip described above.

Through the following detailed descriptions of exemplary embodiments of the present disclosure with reference to the accompanying drawings, other features and advantages of the present disclosure will become clearer.

### BRIEF DESCRIPTION OF THE DRAWINGS

The accompanying drawings constituting a part of the specification illustrate embodiments of the present disclosure and are used together with the specification for explaining the principle of the present disclosure.

The present disclosure may be understood more clearly based on the following detailed description with reference to the accompanying drawings.

FIG. 1 shows a schematic diagram of a multi-bit register according to the related art.

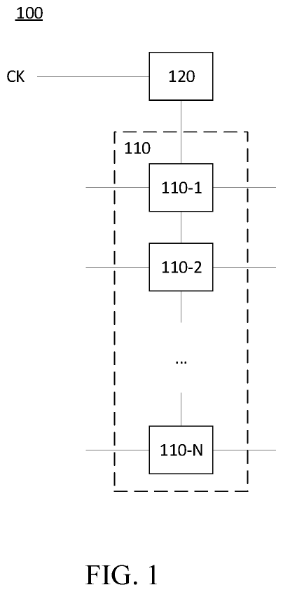

FIG. 2 shows a schematic diagram of a multi-bit register according to some exemplary embodiments of the present disclosure.

FIG. 3 shows a schematic diagram of a multi-bit register according to some other exemplary embodiments of the present disclosure.

FIG. 4 shows a schematic diagram of a multi-bit register according to still some other exemplary embodiments of the present disclosure.

It should be noted that in the below-illustrated implementations, sometimes the same reference numeral is commonly used among different accompanying drawings to represent the same part or parts with the same function, and repeated illustration thereof is omitted. In some cases, similar numerals or letters are used for indicating similar items, and therefore, once an item is defined in one accompanying drawing, the item does not need to be further discussed in the subsequent accompanying drawings.

For ease of understanding, the position, size, range and the like of each structure shown in the accompanying drawings and the like may sometimes not indicate the actual position, size, range and the like. Therefore, the present disclosure is not limited to the position, size, range and the like disclosed in the accompanying drawings and the like.

### DETAILED DESCRIPTION

Various exemplary embodiments of the present disclosure are described below in detail with reference to the accompanying drawings. It should be noted that unless illustrated specifically otherwise, the relative arrangement of the components and steps, the numerical expressions and the values stated in these embodiments do not limit the scope of the present disclosure.

In fact, the following description of at least one exemplary embodiment is merely illustrative, and is not as any limitation to the present disclosure and to application or use thereof. That is, the structures and the methods herein are given in an exemplary manner to illustrate different embodiments of the structures and the methods in the present disclosure. However, one skilled in the art will understand that they merely illustrate exemplary, rather than exhaustive manners in which the present disclosure may be implemented. In addition, the accompanying drawings are not necessarily drawn to scale, and some features may be enlarged to show details of the particular component.

Technologies, methods and devices known to a person of ordinary skill in the related art may not be discussed in detail, but the technologies, methods and devices shall be regarded as a part of the authorized specification where appropriate.

In all examples shown and discussed herein, any specific value should be interpreted only as an example but not as a limitation. Therefore, other examples of the exemplary embodiments may have different values.

A speed of a multi-bit register is a very important performance indicator. The speed of the multi-bit register 100 in the related art needs to be further increased. Therefore, a new technology is needed. One of objectives of the present disclosure is to provide an improved multi-bit register.

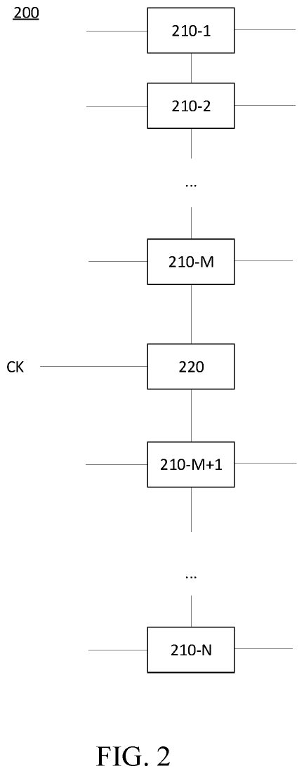

FIG. 2 is a schematic diagram of a multi-bit register 200 according to some exemplary embodiments of the present disclosure. The multi-bit register 200 is configured to store multi-bit data.

As shown in FIG. 2, the multi-bit register 200 includes N register units 210-1, 210-2, . . . , and 210-N and a clock buffer 220.

The N register units 210-1, 210-2, . . . , and 210-N are configured to store the multi-bit data having N bits. Each of the register units 210-1, 210-2, . . . , and 210-N is configured to store a bit of the data. Data input ends and data output ends of the N register units 210-1, 210-2, . . . , and 210-N are respectively connected in parallel, thereby synchronously storing the bits of the multi-bit data.

The clock buffer 220 is configured to provide a clock signal for the N register units 210-1, 210-2, . . . , and 210-N. The clock buffer 220 receives a clock signal from a clock signal end CK and buffers the clock signal, after which the clock signal is input to clock input ends of the N register units 210-1, 210-2, . . . , and 210-N, respectively.

As shown in FIG. 2, the clock buffer 220 is arranged at an intervening position of an array of the N register units 210-1, 210-2, . . . , and 210-N. That is, M register units 210-1, 210-2, . . . , and 210-M are arranged in front of the clock buffer 220, and (N-M) register units 210-M+1, . . . , and 210-N are arranged behind the clock buffer 220.

By arranging the clock buffer 220 at the intervening position of the array of the N register units 210-1, 210-2, . . . , and 210-N, wiring distances from the clock buffer 220 to the clock input ends of the register units 210-1, 210-2, . . . , and 210-N can be shortened, thereby reducing parasitic resistances and parasitic capacitances of the metal wires, and thus increasing the speed of the multi-bit register 200.

In the embodiment shown in FIG. 2, the N register units 210-1, 210-2, . . . , and 210-N and the clock buffer 220 are arranged into a column. In some embodiments, the clock buffer 220 is arranged at a substantially middle position of the column. That is, the clock buffer 220 is arranged behind the M register units 210-1, 210-2, . . . , and 210-M, wherein M is substantially equal to N/2. This may further optimize the wiring distances from the clock buffer 220 to the clock input ends of the register units 210-1, 210-2, . . . , and 210-N, thereby reducing the parasitic resistances and the parasitic capacitances of the metal wires, and thus increasing the speed of the multi-bit register 200.

It should be noted that, “substantially equal” and similar expressions herein mean that the two are approximately equal within a certain error, but not necessarily strictly and precisely equal. For example, “substantially equal” means that the two are approximately equal within a 10% error. In some embodiments, the two are approximately equal within a 5% error. In some contexts, the error may be about 20%. One skilled in the art should understand that this conforms to technical principles and engineering practice. For example, as described above, that M is substantially equal to N/2 means that M is approximately equal to N/2 within a certain error. For example, in an embodiment where N is an odd number, M may be equal to (N−1)/2 or (N+1)/2.

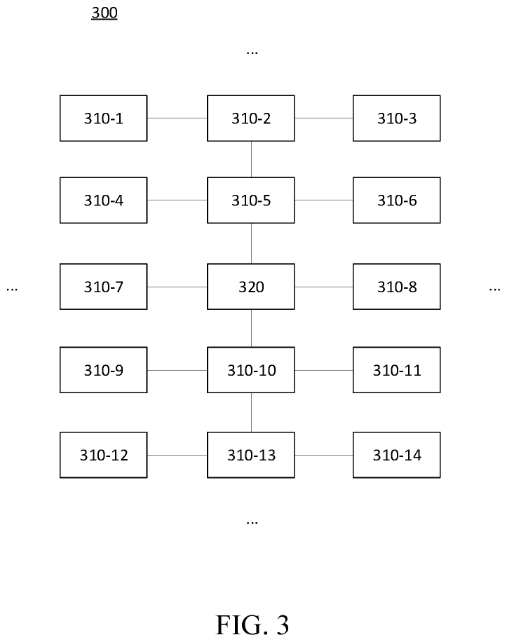

FIG. 3 is a schematic diagram of a multi-bit register 300 according to some other exemplary embodiments of the present disclosure. The multi-bit register 300 is configured to store multi-bit data.

As shown in FIG. 3, the multi-bit register 300 includes a plurality of register units 310-1, 310-2, . . . , and a clock buffer 320. Each register unit is configured to store a bit of the data, and data input ends and data output ends (not shown in FIG. 3 for clarity) of the plurality of register units 310-1, 310-2, . . . , are connected in parallel to each other, thereby synchronously storing the bits of the multi-bit data.

FIG. 3 schematically shows 14 register units 310-1, 310-2, . . . , and 310-14. However, it should be understood by one skilled in the art that the number of register units in the multi-bit register 300 is not limited thereto. The number of register units in the multi-bit register 300 may be determined as required and the register units may be arranged according to the manner schematically shown in FIG. 3.

The clock buffer 320 is configured to provide a clock signal for the plurality of register units 310-1, 310-2, . . . . Clock signal wires are connected between the clock buffer 320 and the plurality of register units 310-1, 310-2, . . . . The clock buffer 320 receives a clock signal from a clock signal end CK (not shown in FIG. 3 for clarity) and buffers the clock signal, after which the clock signal is input to the clock input end of each register unit, respectively.

As shown in FIG. 3, the clock buffer 320 is arranged at an intervening position of an array of the plurality of register units 310-1, 310-2, . . . . Specifically, in the embodiment shown in FIG. 3, the plurality of register units 310-1, 310-2, . . . , and the clock buffer 320 are arranged into a matrix-like configuration, and the clock buffer 320 is arranged at an intervening position of the matrix-like configuration.

In the embodiment shown in FIG. 3, the clock buffer 320 and the plurality of register units 310-1, 310-2, . . . , are arranged into the matrix-like configuration, which can further reduce wiring distances from the clock buffer 320 to the clock input ends of the register units 310-1, 310-2, . . . , as compared with the embodiment shown in FIG. 2, thereby reducing parasitic resistances and parasitic capacitances of the metal wires, and thus increasing the speed of the multi-bit register 300.

In some embodiments, the clock buffer 320 is arranged at a substantially middle position of the matrix-like configuration. For example, as schematically shown in FIG. 3, the clock buffer 320 and the 14 register units 310-1, 310-2, . . . , and 310-14 are arranged into a matrix of 5 rows and 3 columns, and the clock buffer 320 is arranged at the third row and the second column of the matrix.

However, one skilled in the art should understand that the number and the arrangement manner of the register units in the multi-bit register are not limited thereto. In some embodiments, the clock buffer and the plurality of register units may not be arranged into a regular matrix, but arranged into a matrix-like configuration similar to a matrix. For example, the clock buffer and the plurality of register units may be arranged into a matrix shape, wherein at least one row may have fewer columns than other rows, or at least one column may have fewer rows than other columns.

The numbers of rows and columns of the matrix-like configuration formed by the clock buffer and the plurality of register units may be determined according to requirements of the configuration of the register units, the configuration of a chip including the multi-bit register, and the semiconductor process. In some embodiments, a ratio of the number of rows to the number of columns of the matrix-like configuration can be such set that wiring distances from the clock buffer to clock input ends of corresponding register units at the topmost row, the bottommost row, the leftmost column, and the rightmost column of the matrix-like configuration (for example, register units closest to the clock buffer in corresponding rows or columns) are substantially equal. In some embodiments, the ratio of the number of rows to the number of columns of the matrix-like configuration may be greater than or equal to 0.5 and less than or equal to 3.

On the other hand, in some embodiments, the clock buffer may not be arranged at the strictly middle position of the matrix-like configuration, but arranged at the approximately middle position of the matrix-like configuration within a certain error. For example, the matrix-like configuration may have an even number of rows (or an even number of columns), and the clock buffer may be arranged at one of two middle rows (or at one of two middle columns) of the matrix or the matrix-like configuration. In addition, the matrix-like configuration may not be axisymmetric or centrally symmetric, and the clock buffer may be arranged at the approximately middle position of the matrix-like configuration, so that wiring distances from the clock buffer to clock input ends of register units at the outermost edges of the matrix-like configuration are substantially equal.

In the embodiment shown in FIG. 3, there is only one clock signal path between the clock buffer 320 and each of the register units 310-1, 310-2, . . . . In other words, a clock signal is provided from the clock buffer 320 to each of the register units 310-1, 310-2, . . . , through only one path. In other embodiments, a better wiring manner can be used to further increase the speed of the multi-bit register.

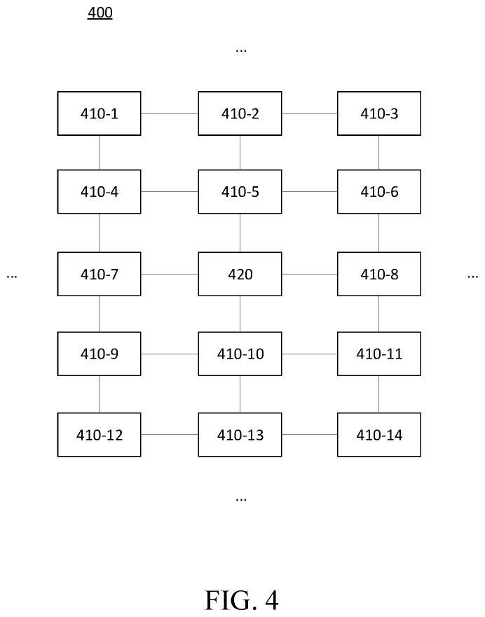

FIG. 4 is a schematic diagram of a multi-bit register 400 according to still some other exemplary embodiments of the present disclosure. The multi-bit register 400 is configured to store multi-bit data.

As shown in FIG. 4, the multi-bit register 400 includes a plurality of register units 410-1, 410-2, . . . , and a clock buffer 420. Each register unit is configured to store a bit of the data, and data input ends and data output ends (not shown in FIG. 4 for clarity) of the plurality of register units 410-1, 410-2, . . . , are connected in parallel to each other, thereby synchronously storing the bits of the multi-bit data.

FIG. 4 schematically shows 14 register units 410-1, 410-2, . . . , and 410-14. However, it should be understood by one skilled in the art that the number of register units in the multi-bit register 400 is not limited thereto. Similarly, the number of register units in the multi-bit register 400 may be determined as required and the register units may be arranged according to the manner schematically shown in FIG. 4.

The clock buffer 420 is configured to provide a clock signal for the plurality of register units 410-1, 410-2, . . . . Clock signal wires are connected between the clock buffer and the plurality of register units 410-1, 410-2, . . . . The clock buffer 420 receives a clock signal from a clock signal end CK (not shown in FIG. 4 for clarity) and buffers the clock signal, after which the clock signal is input to the clock input end of each register unit.

In the embodiment shown in FIG. 4, the clock buffer 420 and the plurality of register units 410-1, 410-2, . . . , are such arranged that there are two or more clock signal paths between the clock buffer 420 and at least some of the register units (410-1, 410-4, 410-7, . . . ). In other words, the clock signal are provided from the clock buffer 420 to at least some of the register units (410-1, 410-4, 410-7, . . . ) through two or more paths.

In some embodiments, as shown in FIG. 4, the clock buffer 420 and the plurality of register units 410-1, 410-2, . . . , are such arranged that there is a clock signal wire directly connected between any adjacent two of the clock buffer 420 and the plurality of register units 410-1, 410-2, . . . . As shown in FIG. 4, “adjacent” means adjacent in a row direction or a column direction of a matrix-like configuration formed by the clock buffer 420 and the plurality of register units 410-1, 410-2, . . . .

In the embodiment shown in FIG. 4, two or more clock signal paths are formed between the clock buffer 420 and at least some of the register units 410-1, 410-4, 410-7, . . . , which can further reduce parasitic resistances of the metal wires between the clock buffer and the register units as compared with the embodiment shown in FIG. 3. In particular, for the semiconductor process in which the parasitic resistance is dominant relative to the parasitic capacitance, this wiring manner can further increase the speed of the multi-bit register.

It should be noted that the plurality of register units is numbered in FIG. 3 and FIG. 4 for convenience only. One skilled in the art should understand that the numbers (310-1, 310-2, . . . ; 410-1, 410-2, . . . ) of the register units in FIG. 3 and FIG. 4 are neither intended to limit the configuration, number, or order of the register units in any manner, nor intended to designate a certain register unit to store a certain bit of the multi-bit data.

The specific configurations and implementations of the register units and the clock buffers used in the present disclosure may be determined according to requirements of the chip including the multi-bit register and the semiconductor process. For example, the register unit may be a D flip-flop or a latch, may have a non-inverted output or an inverted output, may be a static register or a dynamic register.

The operation circuit according to the present disclosure may be implemented in various appropriate manners, such as software, hardware, or a combination of software and hardware. In an implementation, a chip may include the multi-bit register described above, and the chip may be further included in a computing apparatus.

The terms “in front of”, “behind”, “top”, “bottom”, “above”, “under” and the like in the specification and the claims, if present, are used for a descriptive purpose and are not necessarily used for describing the unchanged relative positions. It should be understood that the terms used in such a way are interchangeable where appropriate, so that the embodiments of the present disclosure described herein, for example, can be operated in other orientations that are different from those shown herein or those described otherwise.

As used herein, the term “exemplary” means “serving as an example, instance, or illustration” rather than as a “model” to be exactly reproduced. Any implementation exemplarily described herein is not necessarily to be explained as preferred or advantageous over other implementations. In addition, the present disclosure is not limited by any stated or implied theory provided in the above technical field, background, summary, or detailed description.

As used herein, the term “substantially” means that any minor variation caused by the defect of the design or manufacture, the tolerance of the device or the element, the environmental influence, and/or other factors is included. The term “substantially” also allows for the difference from the perfect or ideal situation caused by the parasitic effect, noise, and other practical considerations that may exist in the actual implementation.

Moreover, elements, nodes, or features that are “connected” or “coupled” together may be mentioned in the description above. As used herein, unless expressly stated otherwise, “connect” means that one element/node/feature is directly connected to (or directly communicates with) another element/node/feature electrically, mechanically, logically, or in other manners. Similarly, unless expressly stated otherwise, “couple” means that one element/node/feature may be directly or indirectly linked with another element/node/feature mechanically, electrically, logically or in other manners, to allow an interaction, even though the two features may not be directly connected. That is, “couple” intends to include both direct and indirect links of the elements or other features, including the connections using one or more intermediate elements.

Furthermore, terms like “first” and “second” and so on may also be used herein for a reference purpose only, and thus are not intended for a limitation. For example, the terms “first” “second” and other such numerical terms relating to the structure or element do not imply the sequence or the order unless the context clearly indicates otherwise.

It should be further understood that the term “comprise/include”, when used herein, specifies the presence of stated features, integers, steps, operations, units, and/or components, but do not preclude the presence or addition of one or more other features, integers, steps, operations, units, and/or components, and/or combinations thereof.

In the present disclosure, the term “provide” is used broadly for covering all manners of obtaining an object, and therefore “provide an object” includes, but not limited to, “purchase”, “prepare/manufacture”, “arrange/set”, “install/assemble”, and/or “order” the object, etc.

One skilled in the art should realize that the boundary between the foregoing operations is merely illustrative. A plurality of operations may be combined into a single operation, the single operation may be distributed among additional operations, and the operations may be performed at least partially in a time overlapping manner. In addition, alternative embodiments may include a plurality of instances of a particular operation, and the operation order may be changed in other various embodiments. However, other modifications, changes, and replacements are also possible. Therefore, the specification and the accompanying drawings are to be regarded as illustrative rather than limited.

Although some specific embodiments of the present disclosure have been described in detail through examples, one skilled in the art should understand that the foregoing examples are only for description, but not for limiting the scope of the present disclosure. The embodiments disclosed herein may be randomly combined without departing from the spirit and scope of the present disclosure. It should also be understood by one skilled in the art that various modifications may be made to the embodiments without departing from the scope and spirit of the present disclosure. The scope of the present disclosure is defined by the appended claims.

1. A multi-bit register comprising:
a plurality of register units, each of which is configured to store a bit of data, and the plurality of register units being connected in parallel to each other; and
a clock buffer configured to provide a clock signal for the plurality of register units, wherein
the plurality of register units is arranged into an array of register units, and the clock buffer is arranged at an intervening position of the array of register units.

2. The multi-bit register according to claim 1, wherein the plurality of register units and the clock buffer are arranged into a column.

3. The multi-bit register according to claim 2, wherein the clock buffer is arranged at a substantially middle position of the column.

4. The multi-bit register according to claim 1, wherein the plurality of register units and the clock buffer are arranged into a matrix-like configuration.

5. The multi-bit register according to claim 4, wherein the clock buffer is arranged at a substantially middle position of the matrix-like configuration.

6. The multi-bit register according to claim 4, wherein in the matrix-like configuration, clock signal wires are connected between the clock buffer and the plurality of register units, so that the clock buffer provides the clock signal for at least a part of the plurality of register units through two or more paths.

7. The multi-bit register according to claim 6, wherein in the matrix-like configuration, a clock signal wire is directly connected between any adjacent two of the clock buffer and the plurality of register units.

8. The multi-bit register according to claim 4, wherein a ratio of the number of rows to the number of columns of the matrix-like configuration is greater than or equal to 0.5 and less than or equal to 3.

9. A chip comprising the multi-bit register according to claim 1.

10. A computing apparatus comprising the chip according to claim 9.
